(19) United States
(12) Patent Application Publication
(10) Pub. No.: US 2025/0054907 A1
(43) Pub. Date: Feb. 13, 2025

(54) POWER MODULE AND METHOD FOR PRODUCING SAME

(71) Applicant: Robert Bosch GmbH, Stuttgart (DE)

(72) Inventor: Irfan Aydogmus, Nuertingen (DE)

(21) Appl. No.: 18/795,493

(22) Filed: Aug. 6, 2024

(30) Foreign Application Priority Data
Aug. 11, 2023 (DE) 10 2023 207 743.4

(51) Int. Cl. H01L 25/065; H01L 23/00; H01L 23/31; H01L 23/36; H01L 23/538; H01L 29/78

(52) U.S. Cl. CPC H01L 25/0655; H01L 23/5386; H01L 24/45; H01L 24/48; H01L 23/3107; H01L 23/36; H01L 23/5387; H01L 24/85; H01L 29/78; H01L 2224/45124; H01L 2224/45147; H01L 2224/48177; H01L 2224/85986

(57) ABSTRACT

A power module. The power module having a first circuit carrier, which circuit carrier has an electrically insulating layer on which at least one first conductor structure, at least one second conductor structure, and at least one third conductor structure are formed. A layout of the first circuit carrier is mirror-symmetrical to a central longitudinal axis. A second circuit carrier, which is a rectangular flexible printed circuit board, is arranged symmetrically to the central longitudinal axis. Contact regions of the flexible printed circuit board are connected to the first and second semiconductor switches of the first bonding wires. The first semiconductor switches are connected to the first conductor structure via second bonding wires. The second semiconductor switches are connected to the third conductor structure via second bonding wires.

### CROSS REFERENCE

The present application claims the benefit under 35 U.S.C. § 119 of German Patent Application No. DE 10 2023 207 743.4 dated Aug. 11, 2023, which is expressly incorporated herein by reference in its entirety.

### FIELD

The present invention relates to a power module with a first circuit carrier, which circuit carrier has an electrically insulating layer on which at least one first conductor structure is formed. The present invention also relates to a method for producing a power module and to a power module bridge comprising a number of power modules.

### BACKGROUND INFORMATION

In the related art, power modules, which are installed in a power module bridge, for example, are additionally molded. During molding, the power module is embedded in a solid protective housing, for example made of plastic (molding compound). The molding compound is used to enclose and protect the interior of the power module. However, these enclosures of the power module by means of molding compound are not particularly resistant to cracks.

German Patent Application No. DE 11 2017 004 390 T5 describes a power module that has the following features: an insulating substrate with a front side to which a power semiconductor element is fastened; a base plate connected to a rear side of the insulating substrate; a housing fastened to the base plate and surrounding the insulating substrate; a cover fastened to the housing and forming a sealed region; and a silicone gel serving as a filling element which fills the entire sealed region and has an internal stress that acts as a compressive stress.

German Patent No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the corresponding first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces.

Furthermore, the power module comprises at least two third contact faces on the surface, wherein the at least two second power transistors each have a further contact face on their sides facing away from the surface of the circuit carrier, and in each case a second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case a first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to an example embodiment of the present invention, a power module is provided, with a first circuit carrier, which has an electrically insulating layer on which are formed at least one first conductor structure, which can be contacted with a first supply terminal via at least one external contact region, at least one second conductor structure, which can be contacted with a second supply terminal via at least one external contact region, and at least one third conductor structure, which can be contacted with a load terminal via at least one external contact region, wherein at least one first semiconductor switch is electrically connected between the at least one first conductor structure and the at least one third conductor structure, wherein at least one second semiconductor switch is electrically connected between the at least one third conductor structure and the at least one second conductor structure, wherein at least one second circuit carrier is arranged spatially in parallel above the first circuit carrier and has at least one internal contact region, at which control terminals of the first and second semiconductor switches are contacted, and at least one external contact region, on which contact elements are arranged, which can be contacted with control lines of an external contact device, wherein a layout of the first circuit carrier is mirror-symmetrical to a central longitudinal axis, and wherein the second circuit carrier is designed as a rectangular and in particular flexible printed circuit board, which is arranged symmetrically to the central longitudinal axis. The first semiconductor switches are connected to the first conductor structure via first bonding wires, and the second semiconductor switches are connected to the third conductor structure via first bonding wires. Furthermore, contact regions of the flexible printed circuit board are connected to the first and second semiconductor switches via second bonding wires.

In the solution provided according to the present invention, the electronic circuit can be implemented with electrical connections, in particular copper bonds, so that existing production lines are reusable and no new or further development and redesign of processes is required.

Advantageously, in the power module according to an example embodiment of the present invention, the first and/or the second bonding wires are designed as copper bonds. Alternatively, it is possible to design the first and/or second bonding wires as aluminum bonds in the power module proposed according to the present invention.

In the power module provided according to an example embodiment of the present invention, the first semiconductor switches and the second semiconductor switches are designed as transistors, in particular MOSFETs (field effect transistors).

The power module provided according to an example embodiment of the present invention is further characterized in that the second bonding wires run as aluminum bonds between the control terminals of the first and second semiconductor switches and the contact regions of the flexible printed circuit board.

In the power module provided according to an example embodiment of the present invention, the first bonding wires are designed as copper bonds between the first and second semiconductor switches and the contact regions of the first and third conductor structures.

The present invention further relates to a power module bridge with a number of power modules, wherein a number of power modules are arranged on a cooling surface and are combined to form a power module bridge, wherein each of the power modules is assigned a separate cooling region.

In a development of the power module bridge provided according to the present invention, it comprises power modules that are each enclosed by a gel frame that is filled with a gel. The gel has a favorable viscosity, which on the one hand compensates for deformations and on the other hand provides complete protection of the power module against the environment.

Furthermore, the present invention relates to a method for producing a power module, wherein a first circuit carrier is mirror-symmetrical to a central longitudinal axis, and a second circuit carrier, which has at least one internal contact region and at least one external contact region, and at least one first semiconductor switch and at least one second semiconductor switch are provided, wherein the first semiconductor switch is electrically connected between a first conductor structure and at least one second conductor structure of the first circuit carrier; wherein at least one second semiconductor is electrically connected between the at least one third conductor structure and at least one first or second conductor structure of the first circuit carrier, wherein the at least one second circuit carrier is arranged spatially in parallel with and symmetrically to the central longitudinal axis above the first circuit carrier. The first semiconductor switches are connected to the first conductor structure via first bonding wires, and the second semiconductor switches are connected to the third conductor structure via second bonding wires. In addition, contact regions of a flexible printed circuit board are connected to the first and second semiconductor switches via second bonding wires.

Advantageously, according to the method provided according to an example embodiment of the present invention, power modules that are already populated and contacted can be combined to form a power module bridge.

In a development of the method provided according to the present invention, the respective power modules of a power module bridge are arranged on cooling regions of a cooling surface.

In an advantageous development of the method provided according to the present invention, the power modules are enclosed by a gel frame that is filled with a gel.

By means of the power module provided according to the present invention or the method for the production thereof, electrical connections can be implemented in particular as wire connections on a power module. Advantageously, the electrical connections can be designed as copper wires or aluminum wires or the like, so that no new process designs are required and production lines that have already been tried and tested can be used. The solution proposed according to the present invention is characterized in particular by its robustness and versatility. Electrical connections in the form of copper bonds or aluminum bonds can be manufactured in an alternating sequence in the smallest of spaces, wherein the individual electrical connections have flat portions that can be integrally bonded particularly easily to conductor structures, and comprise arcuate regions with which insulation channels can be bridged. Furthermore, bonding wires are characterized by the fact that they can be routed very flexibly and adapted to a wide variety of geometries, in particular of power modules that are arranged one above the other.

Following the solution provided according to the present invention, the individual power modules can be combined next to one another on a cooling surface, resulting in a power module bridge that comprises a plurality of the power modules proposed according to the present invention. The cooling surface on which, for example, three power modules arranged next to one another can be accommodated is divided in such a way that each of the power modules is assigned a separate cooling region. The solution proposed according to the present invention can furthermore provide a gel frame that, for example, encloses three power modules according to the present invention, which are combined to form a power module bridge, and keeps them open on one side. To safeguard or protect the components of the power modules proposed according to the present invention, now connected to one another as a power module bridge, the gel frame can be filled with a gel from its open side so that the components of the power modules are reliably protected against environmental influences, heat and other external influences. Due to the viscosity of the gel, thermal expansion or deformation can also be easily compensated for, and therefore the promotion of cracking and thus ingress of moisture can be avoided.

Furthermore, a symmetrical connection, which is very advantageous in electrical terms, is advantageously arranged; cf. section X (T-plus path) and section Y (phase path). All the semiconductor components or chips can thereby be loaded uniformly. Even in the event of a short circuit, the energy can be absorbed uniformly by the semiconductor components. This means that, for example, when used in an electrically powered vehicle, the vehicle can be safely isolated from the current path, and other components within the electrically powered vehicle can be protected very elegantly in this way.

### BRIEF DESCRIPTION OF THE DRAWINGS

The present invention is described in more detail below with reference to the figures.

FIG. 1A-1C show different stages of the construction of a power module according to an example embodiment of the present invention populated with semiconductor switches on different conductor structures and a flexible printed circuit board.

FIG. 2A shows the power module according to FIG. 1C with first bonding wires running between the semiconductor switches and parts of conductor structures.

FIG. 2B is an enlarged diagram of the electrical connection in the form of bonding wires, which are manufactured as copper bonds and arranged in an alternating order.

FIG. 2C shows the formation of second bonding wires between the semiconductor switches starting from their control terminals and contact regions of the flexible printed circuit board.

FIG. 3 is the plan view of a cooling surface divided into cooling regions.

FIG. 4 shows the arrangement of fully contacted and populated power modules on corresponding cooling regions of the cooling surface.

FIG. 5 shows the arrangement of a gel frame around three power modules according to the present invention, which form a power module bridge.

FIG. 6 shows the arrangement of T-minus and phase busbars on the arrangement according to FIG. 5.

FIG. 7 shows the arrangement of T-plus busbars with insulation above the gel frame of the power module bridge, comprising three power modules according to the present invention.

### DETAILED DESCRIPTION OF EXAMPLE EMBODIMENTS

In the following description of the embodiments of the present invention, identical or similar elements are denoted by the same reference signs, a repeated description of these elements in individual cases being dispensed with. The figures show the subject matter of the present invention only schematically.

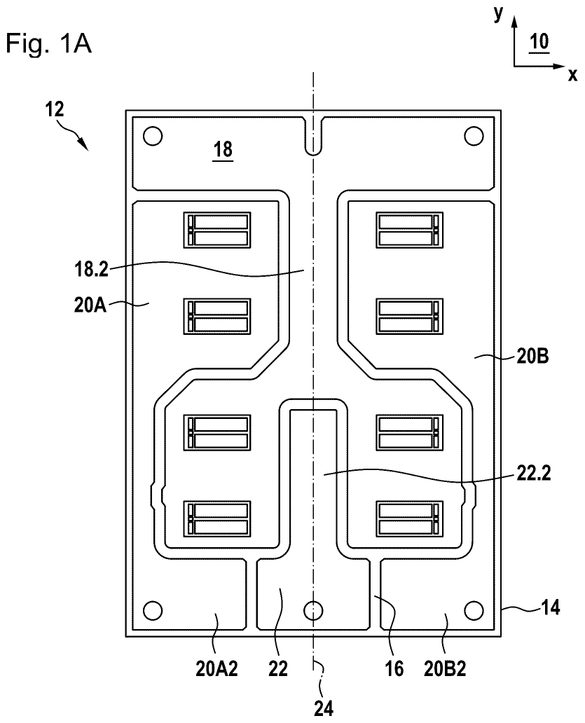

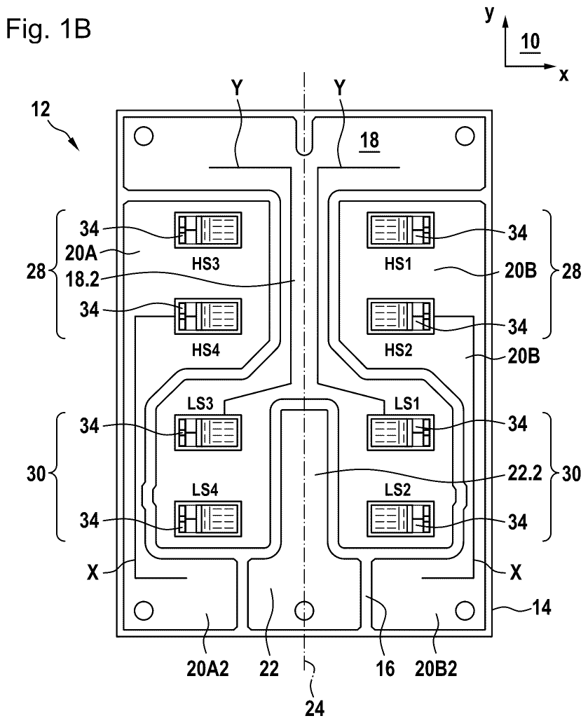

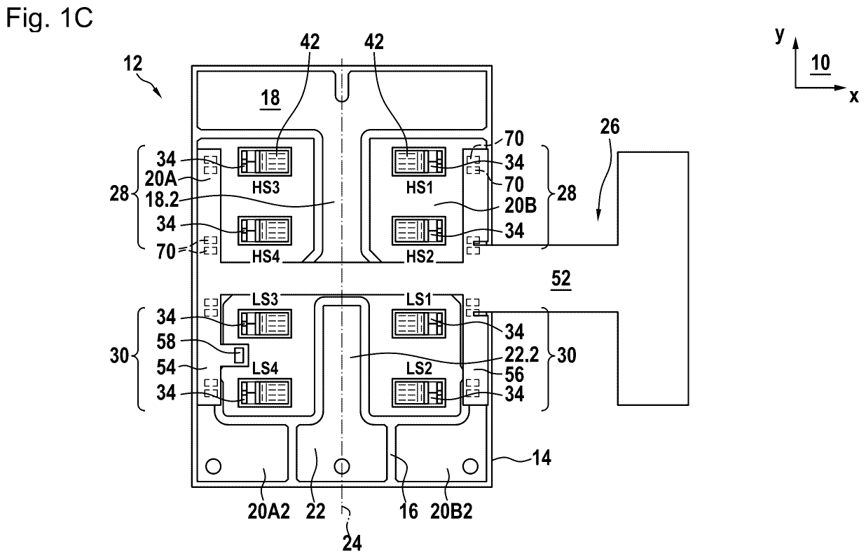

It can be seen in the figure sequence of FIG. 1A to 1C that a power module 12 according to the present invention, which is arranged in an XY plane 10, comprises a first circuit carrier 14. This has an electrical insulation layer 16. Formed on this are at least one first conductor structure 18, which can be contacted with a first supply terminal via at least one external contact region 18.2, at least one second conductor structure 20a, 20b, which can be contacted with a second supply terminal via at least one external contact region 20a.2, 20b.2, and at least one third conductor structure 22, which can be contacted with a load terminal via at least one external contact region 22.2.

It can be seen in the diagram according to FIG. 1A that the individual conductor structures 18, 20a, 20b, 22 are separated from one another by channels, so that there is no electrically conductive connection 58 between them. The power module 12 or the first circuit carrier 14 according to FIG. 1A is constructed symmetrically in relation to its central longitudinal axis 24.

FIG. 1B shows that at least one first semiconductor switch 28 (HS1-HS4) is arranged on the second conductor structures 20a, 20b. Furthermore, at least one second semiconductor switch 30 (LS1-LS4) is accommodated on the lower part of the first conductor structure 18. The semiconductor switches 28, 30 (HS1-HS4, LS1-LS4) are, for example, semiconductor components 42 such as MOSFETs or other transistors. These each have control terminals 34, wherein the semiconductor switches 28, 30 (HS1-HS4, LS1-LS4) can be sintered onto the respective conductor structures 20a, 20b, 18 or are integrally bonded thereto in another way.

In the diagram according to FIG. 1B, two sections X, Y are also shown, wherein a section X corresponds to a symmetrical current-carrying connection on a T-plus path, and a section Y corresponds to a symmetrical connection on a phase path. The symmetrical connections shown can, for example, correspond to symmetrical current paths, which result in uniform loading of semiconductor components 42 or semiconductor switches 28, 30. Due to the symmetrical current paths X, Y shown in FIG. 1B, the energy can be uniformly absorbed by the semiconductor components 42 if a short circuit occurs, so that in the event that these are incorporated in an electrically powered vehicle, for example in its power electronics, a safe isolation from the current path takes place, and other components in the vehicle can be effectively protected.

FIG. 1C shows that a second circuit carrier 26 in the form of a flexible printed circuit board 52 is mounted on the populated first circuit carrier 14 according to the diagram in FIG. 1B. The flexible printed circuit board 52 comprises at least one temperature sensor 50 (NTC) and a first strip-shaped contact region 54 as well as a second strip-shaped contact region 56 running in parallel therewith. The two contact regions 54, 56 are provided with contact pads 70 for connecting electrically conductive connections 58 as will be described below. The contact pads 70 are mounted in pairs next to one another on the first contact region 54 and the second contact region 56 of the flexible printed circuit board 52.

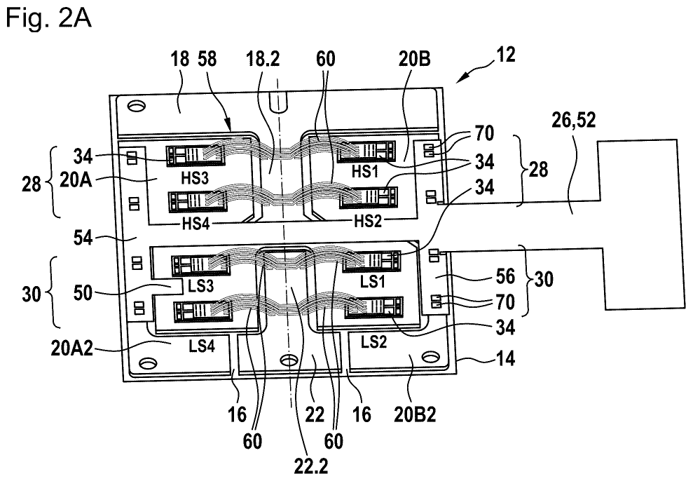

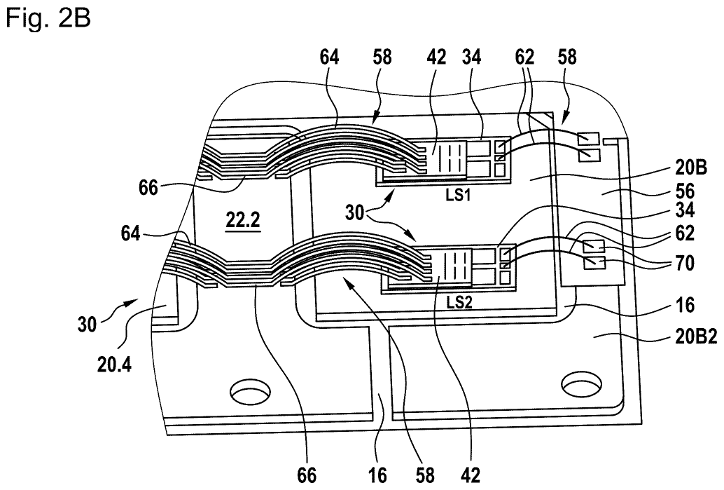

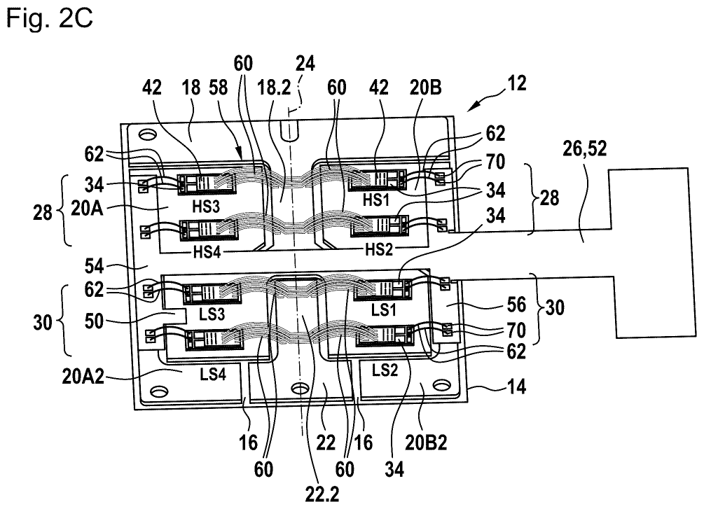

FIG. 2A shows the plan view of a populated and partially contacted first circuit carrier 14 of the power module 12 proposed according to the present invention.

FIG. 2A shows that, starting from the state of the power module 12 according to FIG. 1C, the respective first semiconductor switches 28 (HS1-HS4) and the second semiconductor switches 30 (LS1-LS4) are contacted. In the state shown in FIG. 2A, the control terminals 34 of the semiconductor components 42 designed as MOSFETs are still free and not contacted, but the first semiconductor switches 28 (HS1-HS4) and the second semiconductor switches 30 (LS1-LS4) are contacted with one another via first bonding wires 60, which are preferably designed as copper bonds.

FIG. 2A shows that the first bonding wires 60 are connected as electrically conductive connections 58 with respect to the first semiconductor switches 28 (HS1-HS4) to the external contact region 18.2 of the first conductor structure 18.

The control terminals 34 located on the outside with respect to the first semiconductor switches 28 (HS1-HS4) and the second semiconductor switches 30 (LS1-LS4) are not yet contacted and are located opposite the respective contact pads 70, which are located on the upper side of the first contact region 54 and the second contact region 56 of the flexible printed circuit board 52.

FIG. 2B shows a detail of the partially contacted and populated first circuit carrier 14 in an enlarged view.

It can be seen in the enlarged view according to FIG. 2B that the first bonding wires 60 designed as copper bonds are each arranged next to one another in an alternating sequence 68. Each of the electrical connections 58, here designed as first bonding wires 60, preferably copper bonds, comprises, for example, flat regions 66 contacted with the external contact region 22.2 of the third conductor structure 22. From these, arcuate regions 64 extend on both sides, which are electrically contacted with the individual terminal pads of the semiconductor components 42, preferably designed as MOSFETs. The electrically conductive connections 58 in the form of the first bonding wires 60 as copper bonds run in different arc widths with respect to the arcuate region 64.

On the other hand, it can be seen in FIG. 2B that the control terminals 34, which are still left free in FIG. 2A, of the semiconductor components 42 designed as MOSFETs are contacted with the contact pads 70 of the upper side of the second contact region 56 of the flexible printed circuit board 52 via electrically conductive connections 58 in the form of second bonding wires 62, which are designed as aluminum bonds. The second contact region 56 covers parts of the external contact region 22b.2.

Reference sign 16 denotes the electrical insulation layer applied to the upper side of the first circuit carrier 14.

FIG. 2C shows that in this state the power module 12 proposed according to the present invention is fully populated and fully contacted. FIG. 2C shows that all the control terminals 34 of the first and second semiconductor switches 28, 30 (HS1-HS4, LS1-LS4) are electrically connected to the contact pads 70 on the top side of the first contact regions 54 and the second contact regions 56 of the flexible printed circuit board 52.

In the present case, the electrically conductive connections 58 are designed as second bonding wires 62, for example as aluminum bonds. Instead of aluminum bonds, the second bonding wires 62 could also be made of copper or another electrically highly conductive material. Analogously, according to the diagram in FIG. 2C, the semiconductor components 42, which are MOSFETs, for example, are electrically conductively connected either to the external contact region 18.2 of the first conductor structure 18 or to the external contact region 22.2 of the third conductor structure 22 via the first bonding wires 60, which are designed as copper bonds, for example.

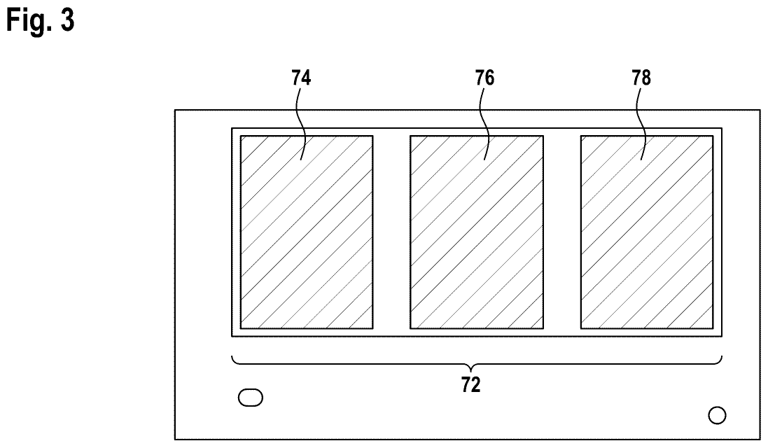

FIG. 3 shows a plan view of a planar layout on which a cooling surface 72 is formed. According to the plan view in FIG. 3, the cooling surface 72 has a number of cooling regions, namely a first cooling region 74, a second cooling region 76 and a third cooling region 78. The individual cooling regions 74, 76, 78 are dimensioned such that the area of the cooling regions 74, 76, 78 corresponds to the base area of the first circuit carrier 14 of the power modules 12 proposed according to the present invention.

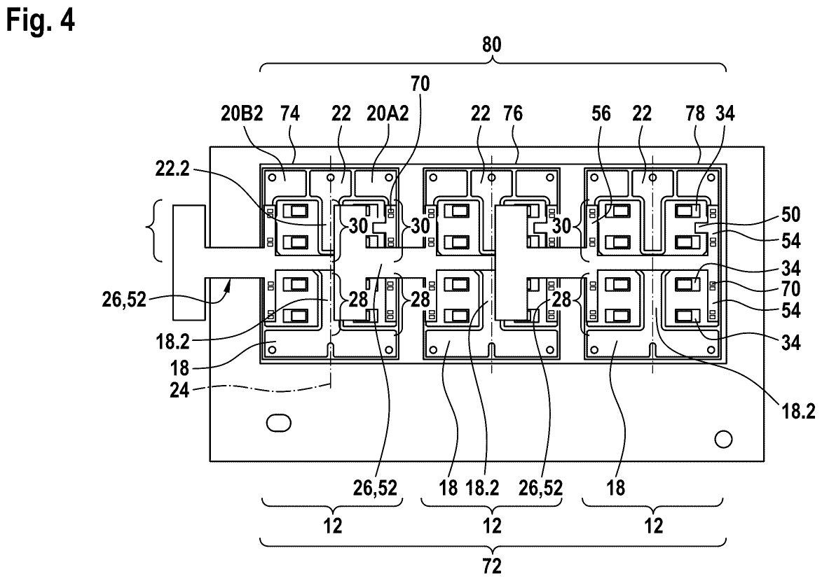

FIG. 4 shows the cooling surface 72 populated with a number of power modules 12. A first circuit carrier 14 of in this case three power modules 12 according to the present invention is mounted on each of the cooling regions 74, 76, 78. The power modules 12 are cooled via the first circuit carrier 14 via the cooling regions 74, 76, 78, so that the thermal load arising during operation is dissipated. In the plan view according to FIG. 4, it can be seen that the three power modules 12 mounted here in an assembly 80 on the cooling surface 72 all correspond to the state of the power modules 12, i.e. fully populated and contacted, as shown in FIG. 2C. The flexible printed circuit boards 52 assigned to each of the power modules 12 and serving as a second circuit carrier 26 are still in a flat design, i.e., extend in the XY plane 10. The respective first and second contact regions 54, 56 of the flexible printed circuit board 52 with the contact pads 70 arranged in pairs thereon are electrically contacted analogously to the diagram according to FIG. 2C via the electrically conductive connections 58 by means of first bonding wires 60 or second bonding wires 62.

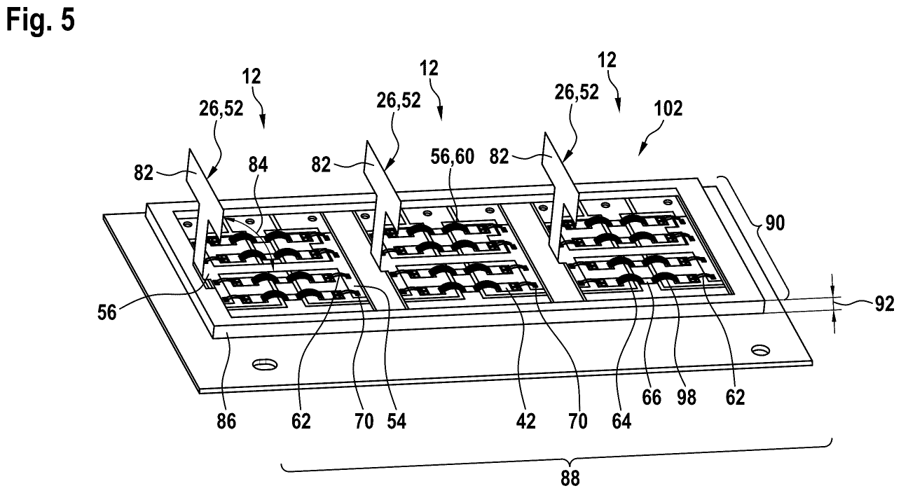

FIG. 5 shows that in this variant the flexible printed circuit boards 52 have a positioning means 82, i.e., the parts of the flexible printed circuit board 52 arranged adjacent to the first contact region 54 have undergone a 90° deflection 84. These therefore extend vertically, i.e., in the Z direction, upward beyond the XY plane 10. Furthermore, it can be seen in the diagram according to FIG. 5 that the arrangement of three power modules 12 on the cooling surface 72 shown as an assembly 80 according to FIG. 4 is enclosed by a gel frame 86, which is rectangular in shape here. The gel frame 86 has a height 92 of a few millimeters and encloses all the power modules 12 that are arranged on the cooling regions 74, 76, 78 of the cooling surface 72. In the variant according to FIG. 5, the gel frame 86 has a first longer side 88 and a shorter side 90 running at right angles thereto. The gel frame 86 is open on one side so that the power modules 12 enclosed thereby can be potted with a gel, for example by filling the gel frame 86 from the top, and are thus protected against environmental influences. Of course, the gel frame 86 is only filled once the fully contacted and populated power modules 12 have been placed into it.

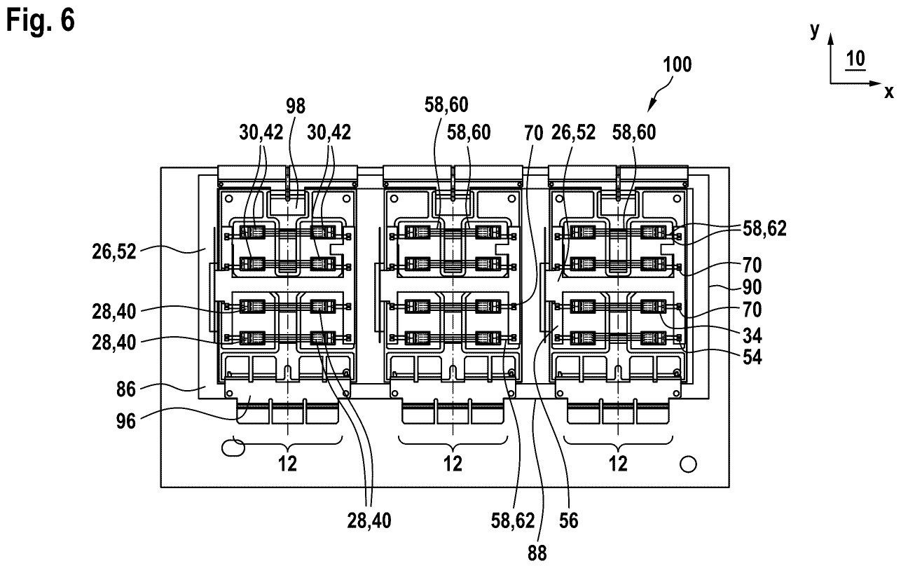

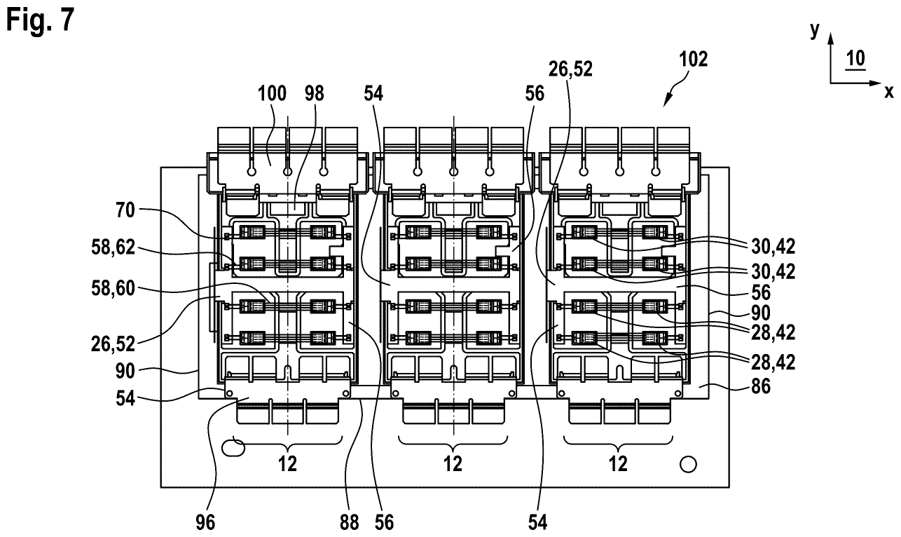

It is clear from the diagram according to FIGS. 6 and 7, proceeding from the state of a power module bridge 102 with three power modules 12 proposed according to the present invention, that these are arranged substantially in the XY plane 10, mounted on their respective cooling regions 74, 76, 78 of the cooling surface 72 and enclosed by the gel frame 86. In the diagram according to FIG. 6, busbars 94 are integrally bonded in this case to a T-minus busbar 96 and to a phase 98. Parts of the individual conductor structures 18, 20a, 20b, 22 are electrically connected via the components mentioned. After the busbars 94 have been integrally bonded, for example by welding, a T-plus busbar 100, which may optionally have insulation, is electrically connected to, for example, the external contact regions 20a.2, 20b.2, as shown in FIG. 7. The phase 98 is electrically connected to the third conductor structure 22, while the T-minus busbar 96 is integrally bonded to the first conductor structure 18; cf. diagram according to FIG. 6.

In the method according to the present invention for producing the power module 12, a first circuit carrier 14 symmetrical to a central longitudinal axis 24, a second circuit carrier 26, which has at least one internal contact region and at least one external contact region, and at least one first semiconductor switch 28 (HS1-HS4) and at least one second semiconductor switch 30 (LS1-LS4) are provided. The first semiconductor switch 28 (HS1-HS4) is electrically connected between at least one first conductor structure 18 and at least one second conductor structure 20a, 20b of the first circuit carrier 14. At least one second semiconductor switch 30 (LS1-LS4) is electrically connected between the at least one third conductor structure 22 and at least the second conductor structure 20a, 20b of the first circuit carrier 14. The at least one second circuit carrier 26 is arranged spatially in parallel with and symmetrically to the central longitudinal axis 24 above the first circuit carrier 14. The first semiconductor switches 28 (HS1-HS4) are connected to the first conductor structure 18 via first bonding wires 60, the second semiconductor switches 30 (LS1-LS4) are connected to the third conductor structure 22 via first bonding wires 60, and the contact regions 54, 56 of the flexible printed circuit board 52 are electrically connected to the first and second semiconductor switches 28, 30 (HS1-HS4, LS1-LS4) via second bonding wires 62.

The present invention is not limited to the exemplary embodiments described here and the aspects emphasized therein. Rather, a large number of modifications are possible within the range indicated by the present invention, which are within the scope of the activities of a person skilled in the art.

What is claimed is:

1. A power module, comprising:
a first circuit carrier including an electrically insulating layer on which are formed at least one first conductor structure, which can be contacted with a first supply terminal via an external contact region, at least one second conductor structure, which can be contacted with a second supply terminal via at least one external contact region, and at least one third conductor structure, which can be contacted with a load terminal via at least one external contact region, wherein at least one first semiconductor switch is electrically connected between the at least one first conductor structure and the at least one third conductor structure, wherein at least one second semiconductor switch is electrically connected between at least one third conductor structure and at least one second conductor structure;
at least one second circuit carrier arranged spatially in parallel above the first circuit carrier and including at least one internal contact region, at which control terminals of the at least one first and second semiconductor switches are contacted, and at least one external contact region, on which contact elements are arranged, which can be contacted with control lines of an external contact device;
wherein a layout of the first circuit carrier is mirror-symmetrical to a central longitudinal axis, and the second circuit carrier is a rectangular flexible printed circuit board, which is arranged symmetrically to the central longitudinal axis, and
wherein contact regions of the flexible printed circuit board are connected to the at least one first and second semiconductor switches via first bonding wires,
wherein the at least one first semiconductor switch is connected to the first conductor structure via at least one second bonding wire, and the at least one second semiconductor switches is connected to the third conductor structure via at least one second bonding wire.

2. The power module according to claim 1, wherein the first and/or the at least one second bonding wires are copper bonds.

3. The power module according to claim 1, wherein the first and/or the at least one second bonding wires are aluminum bonds.

4. The power module according to claim 1, wherein the at least one first and second semiconductor switches are MOSFETs.

5. The power module according to claim 1, wherein the at least one second bonding wire runs as aluminum bonds between the control terminals of the at least one first and second semiconductor switches and the contact regions of the flexible printed circuit board.

6. The power module according to claim 1, wherein the first bonding wires are copper bonds between the at least one first and second semiconductor switches and the external contact regions of the first and third conductor structures.

7. A power module bridge, comprising:
a number of power modules, each including:
a first circuit carrier including an electrically insulating layer on which are formed at least one first conductor structure, which can be contacted with a first supply terminal via an external contact region, at least one second conductor structure, which can be contacted with a second supply terminal via at least one external contact region, and at least one third conductor structure, which can be contacted with a load terminal via at least one external contact region, wherein at least one first semiconductor switch is electrically connected between the at least one first conductor structure and the at least one third conductor structure, wherein at least one second semiconductor switch is electrically connected between at least one third conductor structure and at least one second conductor structure,
at least one second circuit carrier arranged spatially in parallel above the first circuit carrier and including at least one internal contact region, at which control terminals of the at least one first and second semiconductor switches are contacted, and at least one external contact region, on which contact elements are arranged, which can be contacted with control lines of an external contact device,
wherein a layout of the first circuit carrier is mirror-symmetrical to a central longitudinal axis, and the second circuit carrier is a rectangular flexible printed circuit board, which is arranged symmetrically to the central longitudinal axis, and
wherein contact regions of the flexible printed circuit board are connected to the at least one first and second semiconductor switches via first bonding wires, wherein the at least one first semiconductor switch is connected to the first conductor structure via at least one second bonding wire, and the at least one second semiconductor switches is connected to the third conductor structure via at least one second bonding wire;
wherein the number of power modules are combined on a cooling surface to form the power module bridge, wherein each of the power modules is assigned a separate cooling region.

8. The power module bridge according to claim 7, wherein the power modules are enclosed by a gel frame that is filled with a gel.

9. A method for producing at least one power module, the method comprising, for producing each of the at least one power module, the following steps:
providing a first circuit carrier which is mirror-symmetrical to a central longitudinal axis, and a second circuit carrier which is a flexible printed circuit board which has at least one internal contact region and at least one external contact region;
providing at least one first semiconductor switch and at least one second semiconductor switch;
electrically connecting the at least one first semiconductor switch between at least one first conductor structure of the first circuit carrier and at least one third conductor structure of the first circuit carrier;
electrically connecting at least one second semiconductor switch between the at least one third conductor structure and at least one second conductor structure of the first circuit carrier
spatially arranging the second circuit carrier in parallel with and symmetrically to the central longitudinal axis above the first circuit carrier;
wherein the at least one first semiconductor switch is is connected to the first conductor structure via at least one first bonding wire, the at least one second semiconductor switch is connected to the third conductor structure via at least one first bonding wire, and contact regions of the flexible printed circuit board are connected to the at least one first and second semiconductor switches via second bonding wires.

10. The method according to claim 9, wherein at least one more power module includes a plurality of power modules, and wherein, after being popusliated and contacted, are combined to form a power module bridge.

11. The method according to claim 10, wherein the power modules are arranged on cooling regions of a cooling surface.

12. The method according to claim 9, wherein the power modules are enclosed by a gel frame that is filled with a gel.
